(19) United States
(12) Patent Application Publication
(10) Pub. No.: US 2024/0393399 A1
(43) Pub. Date: Nov. 28, 2024

(54) LOW TEMPERATURE STATE-OF-CHARGE CORRECTION FOR A MIXED CHEMISTRY BATTERY

(71) Applicant: GM GLOBAL TECHNOLOGY OPERATIONS LLC, DETROIT, MI (US)

(72) Inventors: Jian Yao, Shanghai (CN); Zhenwen Hu, Shanghai (CN); Chengwu Duan, Shanghai (CN); Yue-Yun Wang, Troy, MI (US)

(21) Appl. No.: 18/363,876

(22) Filed: Aug. 2, 2023

(30) Foreign Application Priority Data
May 24, 2023 (CN) 202310595319.2

(51) Int. Cl. G01R 31/367; G01R 31/36; G01R 31/378; G01R 31/388

(52) U.S. Cl. CPC G01R 31/367; G01R 31/3648; G01R 31/378; G01R 31/388

(57) ABSTRACT

A mixed chemistry battery having a first battery cell having a first chemistry and a second battery cell having a second chemistry that is different than the first chemistry is provided. The first battery cell is connected to the second battery cell in series. The mixed chemistry battery includes a battery monitoring system configured to obtain a first SOC of the first battery cell and a second SOC of the second battery cell and based on a determination that an absolute value of a difference between the first SOC and the second SOC is greater than a threshold value, obtain a first capacity retention rate for the first battery cell and a second capacity retention rate for the second battery cell; and update the second SOC based on the first SOC, the first capacity retention rate, and the second capacity retention rate.

### CROSS-REFERENCE TO RELATED APPLICATIONS

This application claims priority to Chinese Patent Application No. 202310595319.2, filed May 24, 2023, and all the benefits accruing therefrom under 35 U.S.C. § 119, the contents of which in its entirety are herein incorporated by reference.

### INTRODUCTION

The disclosure relates to mixed chemistry batteries. More specifically, the disclosure relates to low temperature correction of the state of charge of a mixed chemistry battery.

Lithium-ion batteries are used in a variety of applications, from electric vehicles to residential batteries to grid-scale applications. In general, the term lithium-ion battery refers to a wide array of battery chemistries that each charge and discharge using reactions from a lithiated metal oxide cathode and a graphite anode. As used herein, a mixed chemistry battery is a lithium-ion battery that includes battery cells that have at least two different chemistries. Two of the more commonly used lithium-ion chemistries are nickel manganese cobalt (NCM) and lithium iron phosphate (LFP). In general, LFP batteries are less expensive to manufacture than NCM batteries and NCM batteries have higher power ratings and energy density compared to LFP batteries.

In general, NCM batteries have better performance than LFP batteries at very low temperatures, (i.e., temperatures below approximately twenty degrees Celsius). More specifically, LFP batteries experience a greater loss of charge capacity than NCM batteries at very low temperatures. NCM battery's state of charge (SOC) varies distinctly by its open-circuit voltage (OCV) level. On the other hand, the LFP battery's SOC level cannot be easily determined based on its OCV due to its flat charge-discharge curve. As a result, accurate SOC estimation of mixed chemistry batteries at very low temperatures is challenging.

### SUMMARY

In one exemplary embodiment, a method for estimating a state-of-charge (SOC) of battery cells of a mixed chemistry battery is provided. The method includes obtaining a first SOC of a first battery cell connected to a second battery cell in series, wherein the first battery cell has a first chemistry and the second battery cell has a second chemistry that is different than the first chemistry and obtaining a second SOC of a second battery cell. Based on a determination that an absolute value of a difference between the first SOC and the second SOC is greater than a threshold value, the method includes obtaining a first capacity retention rate for the first battery cell and a second capacity retention rate for the second battery cell and updating the second SOC based on the first SOC, the first capacity retention rate, and the second capacity retention rate.

In addition to the one or more features described herein the first chemistry is nickel-manganese cobalt and the second chemistry is lithium iron phosphate.

In addition to the one or more features described herein the first SOC of the first battery cell is obtained using a combination of coulomb counting method and a Kalman filter method, and an open-circuit voltage (OCV) inverse lookup method.

In addition to the one or more features described herein the second SOC of the second battery cell is obtained using a combination of coulomb counting method and a Kalman filter method, and an open-circuit voltage (OCV) inverse lookup method.

In addition to the one or more features described herein the updating of the second SOC is further based on a first nominal capacity of the first battery cell and a second nominal capacity of the second battery cell.

In addition to the one or more features described herein the first capacity retention rate is obtained using a table look-up based on the first chemistry and the second capacity retention rate is obtained using a table look-up based on the second chemistry.

In addition to the one or more features described herein the first capacity retention rate and the second retention rate are further determined based on a temperature of the mixed chemistry battery.

In one exemplary embodiment, a vehicle having a mixed chemistry battery is provided. The mixed chemistry includes a first battery cell having a first chemistry and a second battery cell having a second chemistry that is different than the first chemistry is provided. The first battery cell is connected to the second battery cell in series. The mixed chemistry battery includes a battery monitoring system configured to obtain a first SOC of the first battery cell and a second SOC of the second battery cell and based on a determination that an absolute value of a difference between the first SOC and the second SOC is greater than a threshold value, obtain a first capacity retention rate for the first battery cell and a second capacity retention rate for the second battery cell; and update the second SOC based on the first SOC, the first capacity retention rate, and the second capacity retention rate.

In addition to the one or more features described herein the battery monitoring system is further configured to control the charging of the second battery cell based on the updated second SOC.

In addition to the one or more features described herein the first chemistry is nickel-manganese cobalt and the second chemistry is lithium iron phosphate.

In addition to the one or more features described herein the first SOC of the first battery cell is obtained using a combination of coulomb counting method and a Kalman filter method, and an open-circuit voltage (OCV) inverse lookup method.

In addition to the one or more features described herein the second SOC of the second battery cell is obtained using a combination of coulomb counting method and a Kalman filter method, and an open-circuit voltage (OCV) inverse lookup method.

In addition to the one or more features described herein the updating of the second SOC is further based on a first nominal capacity of the first battery cell and a second nominal capacity of the second battery cell.

In addition to the one or more features described herein the first capacity retention rate is obtained using a table look up based on the first chemistry and the second capacity retention rate is obtained using a table look up based on the second chemistry.

In addition to the one or more features described herein the first capacity retention rate and the second retention rate are further determined based on a temperature of the mixed chemistry battery.

In one exemplary embodiment, a computer program product comprising a computer readable storage medium having program instructions embodied therewith is provided. The program instructions are executable by a processor to cause the processor to perform operations that include obtaining a first SOC of a first battery cell connected to a second battery cell in series, wherein the first battery cell has a first chemistry and the second battery cell has a second chemistry that is different than the first chemistry. The operations also include obtaining a second SOC of a second battery cell. Based on a determination that an absolute value of a difference between the first SOC and the second SOC is greater than a threshold value, the operations include obtaining a first capacity retention rate for the first battery cell and a second capacity retention rate for the second battery cell and updating the second SOC based on the first SOC, the first capacity retention rate, and the second capacity retention rate.

In addition to the one or more features described herein the first chemistry is nickel-manganese cobalt and the second chemistry is lithium iron phosphate.

In addition to the one or more features described herein the first SOC of the first battery cell is obtained using a combination of coulomb counting method and a Kalman filter method, and an open-circuit voltage (OCV) inverse lookup method.

In addition to the one or more features described herein the second SOC of the second battery cell is obtained using a combination of coulomb counting method and a Kalman filter method, and an open-circuit voltage (OCV) inverse lookup method.

In addition to the one or more features described herein the updating of the second SOC is further based on a first nominal capacity of the first battery cell and a second nominal capacity of the second battery cell.

The above features and advantages, and other features and advantages of the disclosure are readily apparent from the following detailed description when taken in connection with the accompanying drawings.

### BRIEF DESCRIPTION OF THE DRAWINGS

Other features, advantages and details appear, by way of example only, in the following detailed description, the detailed description referring to the drawings in which:

FIG. 1 is a schematic diagram illustrating a vehicle having a mixed chemistry battery in accordance with an exemplary embodiment;

FIG. 2 is a block diagram illustrating a mixed chemistry battery in accordance with an exemplary embodiment;

FIGS. 3A and 3B are schematic illustrations of the state-of-charge of battery cells of the mixed chemistry at different temperatures in accordance with an exemplary embodiment;

FIG. 4 is a flowchart illustrating a method for estimating the state-of-charge a mixed chemistry battery in accordance with an exemplary embodiment; and

FIG. 5 is a flowchart illustrating a method of charging a mixed chemistry battery in accordance with an exemplary embodiment.

### DETAILED DESCRIPTION

The following description is merely exemplary in nature and is not intended to limit the present disclosure, its application or uses. Various embodiments of the disclosure are described herein with reference to the related drawings. Alternative embodiments of the disclosure can be devised without departing from the scope of the claims. Various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship.

Turning now to an overview of the aspects of the disclosure, embodiments of the disclosure include a mixed chemistry battery having a first battery cell and a second battery cell. The first battery cell is a lithium-ion cell that includes a first chemistry, such as nickel manganese cobalt (NCM), nickel cobalt aluminum (NCA), lithium-ion manganese (LMO), lithium cobalt (LCO), or the like. The second battery cell is a lithium-ion cell that includes a second chemistry, such as lithium iron phosphate (LFP), lithium iron manganese phosphate (LFMP), sodium ion, or the like. NCM battery's state-of-charge (SOC) varies distinctly by its open-circuit voltage (OCV) level. On the other hand, the LFP battery's SOC level cannot be easily determined based on its OCV due to its flat charge-discharge curve.

As discussed above, NCM batteries have better performance than LFP batteries at very low temperatures, (i.e., temperatures below approximately twenty degrees Celsius). More specifically, while both NCM and LFP batteries suffer capacity loss at very low temperatures, the capacity loss of LFP batteries is substantially greater that the capacity loss of NCM batteries. This difference in the capacity loss of the NCM and LFP cells makes estimating the SOC of a mixed chemistry battery difficult.

In exemplary embodiments, retention rates of the NCM and LFP batteries are obtained and used to update the estimated SOC of the LFP batteries. The retention rate of a battery cell is the ratio of the capacity of the battery cell at a current temperature to the capacity of the battery cell at a nominal temperature, (i.e., a temperature of approximately twenty degrees Celsius). In exemplary embodiments, the retention rate is obtained from a lookup table based on the current temperature and the chemistry of the battery cell.

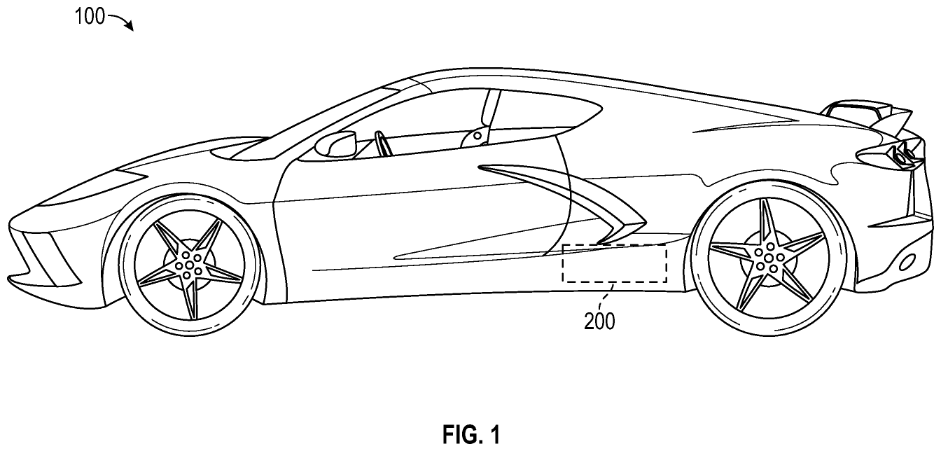

Referring now to FIG. 1, a schematic diagram of a vehicle 100 for use in conjunction with one or more embodiments of the present disclosure is shown. The vehicle 100 includes a mixed chemistry battery 200. In one embodiment, the vehicle 100 is a hybrid vehicle that utilizes both an internal combustion engine and an electric motor powered by the mixed chemistry battery 200. In another embodiment, the vehicle 100 is an electric vehicle that only utilizes electric motors that are powered by the mixed chemistry battery 200.

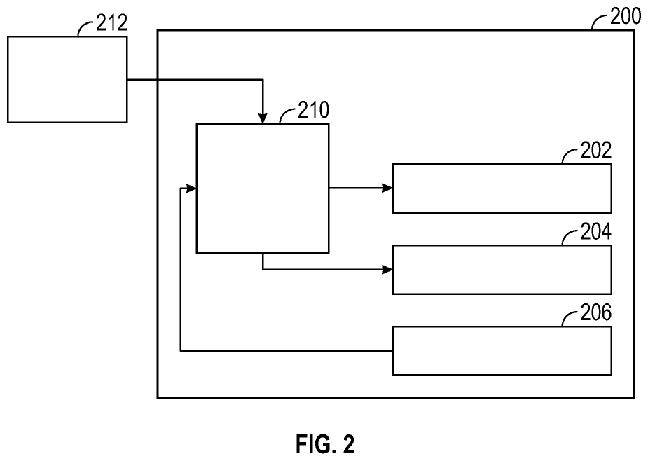

Referring now to FIG. 2 a mixed chemistry battery 200 in accordance with an exemplary embodiment is shown. The mixed chemistry battery 200 includes a first battery cell 202 that is connected in series with a second battery cell 204. In exemplary embodiments, the first battery cell 202 is one of several battery modules in a series connection, each of which consists of a number of cells in the same chemistry, and the second battery cell 204 is one of several battery modules in a series connection, each of which consists of a number of cells in another chemistry. The mixed chemistry battery 200 also includes a battery monitoring system 210 that is configured to measure, via sensors 206, an open circuit-voltage (OCV) of both the first battery cell 202 and the second battery cell 204 as well as the current that flows through the first battery cell 202 and the second battery cell 204. The battery monitoring system 210 is further configured to monitor the temperature of the first battery cell 202 and the second battery cell 204 and to perform other SOC estimation-related functions.

In exemplary embodiments, the battery monitoring system 210 includes one or more of a general processor, a central processing unit, an application-specific integrated circuit (ASIC), a digital signal processor, a field-programmable gate array (FPGA), a digital circuit, an analog circuit, or combinations thereof. In one embodiment, the battery monitoring system 210 also includes a memory in communication with the processor and other components of the battery monitoring system 210. In exemplary embodiments, the battery monitoring system 210 is configured to calculate and track the SOC and SOH of both the first battery cell 202 and the second battery cell 204. In exemplary embodiments, the battery monitoring system 210 is configured to receive power from an external power supply 212 and to control the charging of the first battery cell 202 and the second battery cell 204 based on the SOC of the first battery cell 202 and the second battery cell 204.

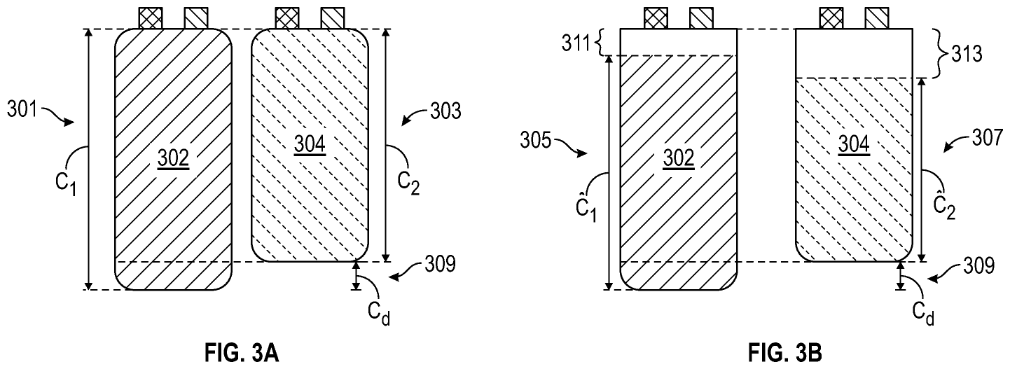

Referring now to FIG. 3A a schematic illustration of the state-of-charge of cells of a mixed chemistry battery at a nominal temperature, (i.e., approximately twenty degrees Celsius) in accordance with an exemplary embodiment is shown. As illustrated, a first battery cell 302, which has a first chemistry, has a first nominal capacity (C₁) 301, and a second battery cell 304, which has a second chemistry that is different that the first chemistry, has a second nominal capacity (C₂) 303. In one embodiment, the first battery cell 302 is an NCM cell and the second battery cell 304 is an LFP cell. The first nominal capacity (C₁) 301 is larger than the second nominal capacity (C₂) 303 by a capacity difference (C_{d}) 309.

Referring now to FIG. 3B a schematic illustration of the state-of-charge of cells of a mixed chemistry battery at a very low temperature, (i.e., approximately negative twenty degrees Celsius) in accordance with an exemplary embodiment is shown. As illustrated, the first battery cell 302 has a first capacity (C₁) 305 and the second battery cell 304 has a second capacity (C₂) 307. The first capacity (C₁) 305 is less than the first nominal capacity (C₁) 301 by a first amount 311 and the second capacity (C₂) 307 is less than the second nominal capacity (C₂) 303 by a second amount 313, which is larger than the first amount 311. The difference between the first amount 311 and the second amount 313 is due to the relatively poorer performance of LFP cells at very low temperatures compared to NCM cells.

In exemplary embodiments, a first capacity retention rate (r₁) for the first battery cell is defined as

$${r}_{1} = \frac{\hat{{C}_{1}}}{{C}_{1}}$$

and a second capacity retention rate (r₂) for the second battery cell is defined as

$${r}_{2} = \frac{\hat{{C}_{2}}}{{C}_{2}} .$$

In exemplary embodiments, the first capacity retention rate (r₁) and the second capacity retention rate (r₂) are constant values that can be obtained from a look up table based on the temperature and chemistry of the first battery cell 302 and the second battery cell 304, respectively.

In exemplary embodiments, the battery monitoring system is configured to measure, via sensors, an open circuit-voltage (OCV) of both the first battery cell and the second battery cell to obtain an estimate of the SOC of the first battery cell and the second battery cell, when the battery cells are not being charged or discharged. During use, (i.e., when the battery cells are being charged or discharged) the battery monitoring system updates the estimated SOC of the battery cells based on the current (i) that flows through the first battery cell and the second battery cell. For example, the change in the SOC of the first battery cell can be calculated as:

$$Δ {SOC}_{1} = \frac{\int idt}{{C}_{1}}$$

and the change in the SOC of the second battery cell can be calculated as:

$$Δ {SOC}_{2} = \frac{{SOC}_{1} \times {C}_{1} - {C}_{d}}{{C}_{2}} .$$

However, in very low temperature environments, due to the differences in the first capacity retention rate (r₁) and the second capacity retention rate (r₂), this estimation of the change in the SOC of the second battery cell will have a large error.

Accordingly, in exemplary embodiments, the change in the SOC of the first battery cell and the second battery cell are calculated by the battery monitoring system based on the first capacity retention rate (r₁) and the second capacity retention rate (r₂). The change in the SOC of the first battery cell is calculated as

$$Δ SO {\hat{C}}_{1} = \frac{\int idt}{{C}_{1} \times {r}_{1}}$$

and the change in the SOC of the second battery cell is calculated as:

$$Δ SO {\hat{C}}_{2} = \frac{\int idt}{{C}_{2} \times {r}_{2}} .$$

In addition, the SOC of the second battery cell at a very low temperature (SOC₂) can be estimated by:

$$SO {\hat{C}}_{2} = \frac{{SOC}_{1} \times \hat{{C}_{1}} \times {r}_{1} - ( {C}_{1} \times {r}_{1} - {C}_{2} \times {r}_{2} )}{{C}_{2} \times {r}_{2}} .$$

In exemplary embodiments, estimates of SOĈ₂ using the above techniques have a substantially smaller error value than traditional estimation techniques that do not take into account the first capacity retention rate (r₁) and the second capacity retention rate (r₂). As a result, the battery monitoring system will have a more accurate estimate of the SOC of the battery cells and can prevent overcharging of the battery cells, which may damage the battery cells, and undercharging of the battery cells, which negatively impacts the range of a vehicle using the battery cells.

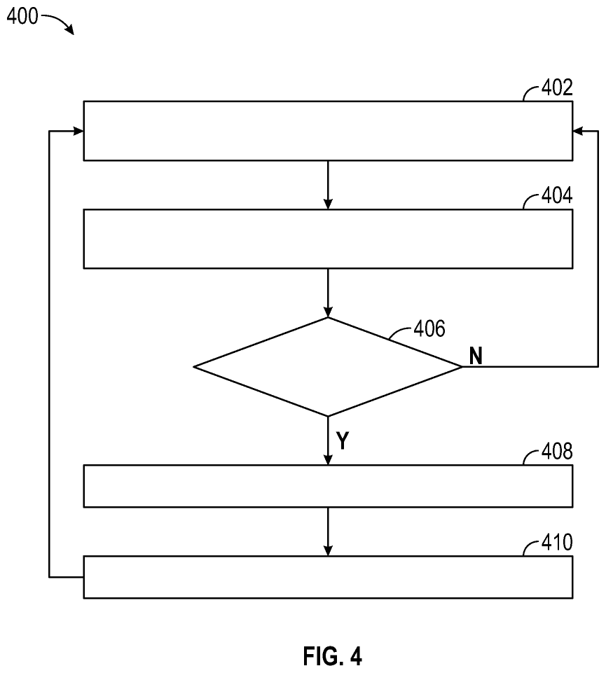

Referring now to FIG. 4, a flowchart illustrating a method 400 for estimating the state-of-charge of a mixed chemistry battery in accordance with an exemplary embodiment is shown. In exemplary embodiments, the method 400 is performed by a battery management system, such as the one shown in FIG. 2. At block 402, the method 400 includes monitoring an open circuit voltage (OCV) of a first battery cell and a second battery cell, the temperature of the first battery cell and the second battery cell, and a current flow through the first battery cell and the second battery cell. Next, at block 404, the method 400 includes obtaining a first state-of-charge (SOC) for the first battery cell and a second SOC for the second battery cell. In exemplary embodiments, the first and second SOC are obtained based at least in part on the monitored OCV, current, and temperature of the first battery cell and a second battery cell. In exemplary embodiments, the SOCs are obtained based on a combination of Coulomb counting techniques and battery state estimation techniques, such as the use of a Kalman filter.

In an exemplary embodiment, a battery state estimation technique includes calculating SOC=a (SOC₁+(1−a)*SOC₂, where a is a weighting factor that is less than one. SOC₁ represents the state of charge calculated from Coulomb counting, SOC₂ represents the state of charge estimated using Kalman filter. In exemplary embodiments, whenever an electric vehicle that includes the mixed chemistry battery is at rest for a sufficient amount of time, the calculated sensing cell SOC is reset to a more accurate value based on OCV-SOC curve.

At decision block 406, the method 400 includes determining if the absolute value of the difference between the first SOC and the second SOC is greater than a threshold value. In exemplary embodiments, the threshold value is approximately ** volts. Based on a determination that the absolute value of the difference between the first SOC and the second SOC is not greater than the threshold value, the method 400 returns to block 402. Otherwise, based on a determination that the absolute value of the difference between the first SOC and the second SOC is greater than the threshold value, the method 400 proceeds to block 408 and obtains capacity retention rates (r₁, r₂) for the first battery cell and the second battery cell. In exemplary embodiments, the capacity retention rates are obtained from a look-up table based on the chemistries and temperatures of the battery cells. Next, at block 410, the method 400 includes updating the estimate of the second SOC based on the first SOC, and the capacity retention rates (r₁, r₂). In one embodiment, the second SOC is calculated by:

$$SO {\hat{C}}_{2} = \frac{{SOC}_{1} \times \hat{{C}_{1}} \times {r}_{1} - ( {C}_{1} \times {r}_{1} - {C}_{2} \times {r}_{2} )}{{C}_{2} \times {r}_{2}} .$$

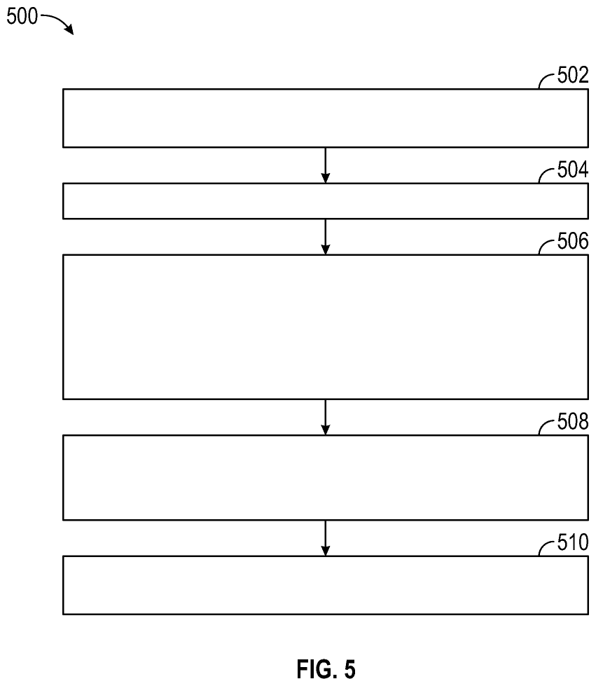

Referring now to FIG. 5, a flowchart illustrating a method 500 for charging a mixed chemistry battery in accordance with an exemplary embodiment is shown. In exemplary embodiments, the method 400 is performed by a battery management system, such as the one shown in FIG. 2. At block 502, the method 500 includes obtaining a first SOC of a first battery cell connected to a second battery cell in series. The first battery cell has a first chemistry and the second battery cell has a second chemistry that is different than the first chemistry. In one embodiment, the first SOC of the first battery cell is obtained using a combination of coulomb counting method and a Kalman filter method, and an open-circuit voltage (OCV) inverse lookup method.

Next, at block 504, the method 500 includes obtaining a second SOC of a second battery cell. In one embodiment, the second SOC of the second battery cell is obtained using a combination of coulomb counting method and a Kalman filter method, and an open-circuit voltage (OCV) inverse lookup method. In exemplary embodiments, the first chemistry is nickel-manganese cobalt and the second chemistry is lithium-iron phosphate.

At block 506, the method 500 includes obtaining a first capacity retention rate for the first battery cell and a second retention rate for the second battery cell, based on a determination that an absolute value of a difference between the first SOC and the second SOC is greater than a threshold value. In exemplary embodiments, the first capacity retention rate is obtained using a table look-up based on the first chemistry and the second capacity retention rate is obtained using a table look-up based on the second chemistry. In one embodiment, the first capacity retention rate and the second retention rate are further determined based on the temperature of the mixed chemistry battery.

Next, at block 508, the method 500 includes updating the second SOC based on the first SOC, the first capacity retention rate, and the second capacity retention rate. In exemplary embodiments, updating the second SOC is further based on the first nominal capacity of the first battery cell and a second nominal capacity of the second battery cell. The method 500 concludes at block 510 by charging the mixed chemistry battery based on the updated second SOC and the first SOC. In exemplary embodiments, the error rate of the updated second SOC, calculated at block 508, is approximately fifty percent or less than the error rate of the second SOC obtained at block 504.

In exemplary embodiments, since the battery monitoring system will have a more accurate estimate of the SOC of the battery cells, the battery management system will prevent overcharging of the battery cells, which may damage the battery cells, and undercharging of the battery cells, which negatively impacts the range of a vehicle using the battery cells.

The terms “a” and “an” do not denote a limitation of quantity, but rather denote the presence of at least one of the referenced item. The term “or” means “and/or” unless clearly indicated otherwise by context. Reference throughout the specification to “an aspect”, means that a particular element (e.g., feature, structure, step, or characteristic) described in connection with the aspect is included in at least one aspect described herein, and may or may not be present in other aspects. In addition, it is to be understood that the described elements may be combined in any suitable manner in the various aspects.

When an element such as a layer, film, region, or substrate is referred to as being “on” another element, it can be directly on the other element or intervening elements may also be present. In contrast, when an element is referred to as being “directly on” another element, there are no intervening elements present.

Unless specified to the contrary herein, all test standards are the most recent standard in effect as of the filing date of this application, or, if priority is claimed, the filing date of the earliest priority application in which the test standard appears.

Unless defined otherwise, technical and scientific terms used herein have the same meaning as is commonly understood by one of skill in the art to which this disclosure belongs.

While the above disclosure has been described with reference to exemplary embodiments, it will be understood by those skilled in the art that various changes may be made and equivalents may be substituted for elements thereof without departing from its scope. In addition, many modifications may be made to adapt a particular situation or material to the teachings of the disclosure without departing from the essential scope thereof. Therefore, it is intended that the present disclosure not be limited to the particular embodiments disclosed, but will include all embodiments falling within the scope thereof.

What is claimed is:

1. A method for estimating a state-of-charge (SOC) of battery cells of a mixed chemistry battery, the method comprises:
obtaining a first SOC of a first battery cell connected to a second battery cell in series, wherein the first battery cell has a first chemistry and the second battery cell has a second chemistry that is different than the first chemistry;
obtaining a second SOC of a second battery cell; and
based on a determination that an absolute value of a difference between the first SOC and the second SOC is greater than a threshold value:
obtaining a first capacity retention rate for the first battery cell and a second capacity retention rate for the second battery cell; and
updating the second SOC based on the first SOC, the first capacity retention rate, and the second capacity retention rate.

2. The method of claim 1, wherein the first chemistry is nickel-manganese cobalt and the second chemistry is lithium iron phosphate.

3. The method of claim 1, wherein the first SOC of the first battery cell is obtained using a combination of coulomb counting method and a Kalman filter method, and an open-circuit voltage (OCV) inverse lookup method.

4. The method of claim 1, wherein the second SOC of the second battery cell is obtained using a combination of coulomb counting method and a Kalman filter method, and an open-circuit voltage (OCV) inverse lookup method.

5. The method of claim 1, wherein the updating of the second SOC is further based on a first nominal capacity of the first battery cell and a second nominal capacity of the second battery cell.

6. The method of claim 1, wherein the first capacity retention rate is obtained using a table look-up based on the first chemistry and the second capacity retention rate is obtained using a table look-up based on the second chemistry.

7. The method of claim 6, wherein the first capacity retention rate and the second retention rate are further determined based on a temperature of the mixed chemistry battery.

8. A vehicle comprising:
a mixed chemistry battery comprising:
a first battery cell having a first chemistry;
a second battery cell having a second chemistry that is different than the first chemistry, wherein the first battery cell is connected to the second battery cell in series; and
a battery monitoring system configured to:
obtain a first SOC of the first battery cell and a second SOC of the second battery cell and based on a determination that an absolute value of a difference between the first SOC and the second SOC is greater than a threshold value:
obtain a first capacity retention rate for the first battery cell and a second capacity retention rate for the second battery cell; and
update the second SOC based on the first SOC, the first capacity retention rate, and the second capacity retention rate.

9. The vehicle of claim 8, wherein the battery monitoring system is further configured to control charging of the second battery cell based on the updated second SOC.

10. The vehicle of claim 8, wherein the first chemistry is nickel-manganese cobalt and the second chemistry is lithium iron phosphate.

11. The vehicle of claim 8, wherein the first SOC of the first battery cell is obtained using a combination of coulomb counting method and a Kalman filter method, and an open-circuit voltage (OCV) inverse lookup method.

12. The vehicle of claim 8, wherein the second SOC of the second battery cell is obtained using a combination of coulomb counting method and a Kalman filter method, and an open-circuit voltage (OCV) inverse lookup method.

13. The vehicle of claim 8, wherein the updating of the second SOC is further based on a first nominal capacity of the first battery cell and a second nominal capacity of the second battery cell.

14. The vehicle of claim 8, wherein the first capacity retention rate is obtained using a table look up based on the first chemistry and the second capacity retention rate is obtained using a table look up based on the second chemistry.

15. The vehicle of claim 14, wherein the first capacity retention rate and the second retention rate are further determined based on a temperature of the mixed chemistry battery.

16. A computer program product comprising a computer readable storage medium having program instructions embodied therewith, the program instructions executable by a processor to cause the processor to perform operations comprising:
obtaining a first SOC of a first battery cell connected to a second battery cell in series, wherein the first battery cell has a first chemistry and the second battery cell has a second chemistry that is different than the first chemistry;
obtaining a second SOC of a second battery cell; and
based on a determination that an absolute value of a difference between the first SOC and the second SOC is greater than a threshold value:
obtaining a first capacity retention rate for the first battery cell and a second capacity retention rate for the second battery cell; and
updating the second SOC based on the first SOC, the first capacity retention rate, and the second capacity retention rate.

17. The computer program product of claim 16, wherein the first chemistry is nickel-manganese cobalt and the second chemistry is lithium iron phosphate.

18. The computer program product of claim 16, wherein the first SOC of the first battery cell is obtained using a combination of coulomb counting method and a Kalman filter method, and an open-circuit voltage (OCV) inverse lookup method.

19. The computer program product of claim 16, wherein the second SOC of the second battery cell is obtained using a combination of coulomb counting method and a Kalman filter method, and an open-circuit voltage (OCV) inverse lookup method.

20. The computer program product of claim 16, wherein the updating of the second SOC is further based on a first nominal capacity of the first battery cell and a second nominal capacity of the second battery cell.
